(19) United States
(12) Patent Application Publication
(10) Pub. No.: US 2020/0108718 A1
(43) Pub. Date: Apr. 9, 2020

(54) MOTOR VEHICLE OPERATING DEVICE

(71) Applicant: BCS AUTOMOTIVE INTERFACE SOLUTIONS GMBH, Radolfzell (DE)

(72) Inventors: NELSON CARVALHO, Aach (DE); PAWEL BOROWCZYK, Czestochowa (PL); STEFFEN SORNBERGER, Hilzingen/Twielfeld (DE); HELMUT SOWIG, Villingen-Schwenn ingen (DE); VIKTOR BELIUZHENKO, Konstanz (DE); LEANDRO CONDE, Singen (DE)

(21) Appl. No.: 16/469,438

(22) PCT Filed: Nov. 13, 2017
(86) PCT No.: PCT/EP2017/079058

§ 371 Date: Jun. 13, 2019

(30) Foreign Application Priority Data
Dec. 16, 2016 (DE) 20 2016 008 348.2
Jun. 21, 2017 (DE) 10 2017 113 659.2

(51) Int. Cl. B60K 35/00; G06F 3/041; H03K 17/96

(52) U.S. Cl. CPC B60K 35/00; G06F 3/0412; H03K 17/9622; H03K 2017/9602; G06F 3/0414; B60K 2370/143; B60K 2370/1468; H03K 17/9643

(57) ABSTRACT

A motor vehicle operating device (10) for an interior of a motor vehicle has an operating surface (26) which has a plurality of switching symbols (28) displayed thereon, each of which having a touch sensor (38) associated therewith. The touch sensors (38) are each configured to detect an approach to and/or a touch of the operating surface (26). The motor vehicle operating device (10) further comprises a plurality of pressure sensors (40) which are associated with the switching symbols (28), the number of pressure sensors (40) being smaller than the number of touch sensors (38).

### RELATED APPLICATIONS

This application corresponds to PCT/EP2017/079058, filed Nov. 13, 2017, which claims the benefit of German Application No. 20 2016 008 348.2, filed Dec. 16, 2016, and German Application No. 10 2017 113 659.2, filed Jun. 21, 2107, the subject matter of which are incorporated herein by reference in their entirety.

### BACKGROUND OF THE INVENTION

The invention relates to a motor vehicle operating device for an interior of a motor vehicle.

From the prior art, motor vehicle operating devices are known which can be used by a vehicle occupant to control functions of a motor vehicle. This may be, for example, a light strip or a light island on which the vehicle lighting can be adjusted. Furthermore, such a light strip or light island may comprise further functions, which the vehicle occupant can control by means of the motor vehicle operating device in question, such as, e.g., windshield or rear window heater, mirror heating or rear fog lamp.

It is known that motor vehicle operating devices are employed which comprise an operating surface on which a plurality of switching symbols are displayed. The switching symbols are printed on keys which are mechanically actuated to activate or deactivate the associated function. The keys have pressure sensors assigned to them which detect the mechanical actuation accordingly.

In this context, it has turned out to be a disadvantage that a separate pressure sensor needs to be provided for each function to be actuated by means of an associated switching symbol, which correspondingly increases the costs and effort involved in manufacturing the motor vehicle operating device.

In addition, modern motor vehicles use, among other things, capacitive motor vehicle operating devices which comprise control elements of capacitive configuration that also include switching symbols. Using the capacitively designed control elements, an approach to and a touch of the operating surface can be detected in a simple manner. Mechanical actuation is not required here. In general, the same functionality can be attained by using the capacitive control elements as with the pressure sensors, that is, activate or deactivate a function.

### SUMMARY OF THE INVENTION

The object of the invention is to provide a motor vehicle operating device that is cost-effective and simple to manufacture while having increased functionality.

The object is achieved according to the invention by a motor vehicle operating device for an interior of a motor vehicle, including an operating surface which has a plurality of switching symbols displayed thereon, each of which having a touch sensor associated therewith, the touch sensors each being configured to detect an approach to and/or a touch of the operating surface, the motor vehicle operating device further including a plurality of pressure sensors which are associated with the switching symbols, the number of pressure sensors being smaller than the number of touch sensors.

The basic idea of the invention is that the motor vehicle operating device has an increased functionality in that different sensors are used which are intended for detecting different operations or actuations of the motor vehicle operating device. The different sensors involved are the touch sensors and the pressure sensors. The touch sensors can be used to detect an approach and/or a touch of the operating surface, whereas the additional pressure sensors detect a pressure exerted on the operating surface, that is, a mechanical actuation that requires a force. Moreover, since the number of pressure sensors is lower than the number of switching symbols, the effort involved in manufacturing the motor vehicle operating device is lower than for the motor vehicle operating devices known from the prior art, which comprise a plurality of pressure sensors that are each assigned to a respective key.

The pressure sensors may be arranged in such a way that they determine, in a triangulation process, in particular taking into consideration the geometry of the operating surface, the location on the operating surface to which the actuating or operating force is applied. Accordingly, the signals detected by the plurality of pressure sensors are evaluated in order to (at least roughly) draw conclusions about the location on the operating surface where the vehicle occupant has pressed on the operating surface.

One aspect provides that the touch sensors and/or the pressure sensors are designed to be capacitive and/or piezoelectric. The touch sensors may be configured as self-capacitive touch sensors so that they detect an approach to the operating surface in a simple manner. The pressure sensors may be designed to be capacitive, with two capacitor plates being provided, for example, whose distance from each other is changed if a pressure is exerted on the operating surface. This is detected accordingly by means of the pressure sensors or the electric field changing as a result, in order to infer a corresponding actuation. Alternatively, the pressure sensors may be formed by piezoelectric sensors, which convert a pressure applied (actuation) to an electrical signal that can be evaluated.

A further aspect provides that the motor vehicle operating device comprises an evaluation unit which is coupled to the touch sensors and the pressure sensors in order to evaluate the data acquired. This means that the respective sensors transmit the data acquired to the evaluation unit, that is, the touch or proximity signals as well as the actuation signals. The evaluation unit evaluates the various signals in order to infer a particular approach/touch or actuation of the motor vehicle operating device, in particular of the operating surface. Here the signals of the different sensors can be linked with each other, for example in order to detect an actuation of a particular switching symbol, even if this switching symbol is not directly assigned a pressure sensor.

More particularly, the touch sensors form a touch sensor system which is configured to detect and locate an approach to and/or a touch of the operating surface. This is done in a simple way in that exactly one touch sensor is assigned to the respective switching symbols, so that the approach to or touch of a switching symbol is detected by means of the associated capacitively designed touch sensor of the touch sensor system. The respective signal is passed on to the evaluation unit, which activates the function associated with the approach or touch. The touch sensor system may further be designed such that it already detects an approach to the entire operating surface of the motor vehicle operating device, i.e. rather than to a specific switching symbol, with the approach to the entire operating surface activating a function, for example a search lighting of the motor vehicle operating device, in order to backlight the individual switching symbols. The search lighting therefore allows the switching symbols available on the operating surface to be found more easily so that they can be actuated accordingly.

Furthermore, the pressure sensors may form an actuation sensor system which is configured to detect a pressure on the operating surface. As soon as the vehicle occupant presses on the operating surface, this is detected by the plurality of pressure sensors, i.e. the actuation sensor system. As already discussed, on the basis of a triangulation process, the pressure sensors can estimate at which position the vehicle occupant has actuated the operating surface. The higher the number of pressure sensors provided, the higher the accuracy of the estimate. In particular, the operating surface is taken into consideration as a boundary condition here.

In an alternative embodiment, the touch sensor system and the actuation sensor system are configured in such a way that together they detect an actuation of one of the plurality of switching symbols. Here, the touch sensor system detects, for example, which switching symbol the operating object concerned has approached before, so that the pressure sensors of the actuation sensor system are merely used for making plausible whether the appropriate switching symbol was actually also actuated by a pressure being exerted on the switching symbol. This allows an unintended actuation due to unintentional touching to be effectively prevented.

By analogy, the actuation sensor system may serve to make the touch sensor system plausible if the touch sensor system reacts to a touch.

In general, the motor vehicle operating device may be configured to detect an approach to the entire operating surface, an approach to one of the plurality of switching symbols, a touch of one of the plurality of switching symbols and/or a pressing of one of the plurality of switching symbols, in particular wherein different functions are associated with the detected states. The approach to the entire operating surface may cause a search lighting to be switched on, so that the switching symbols displayed on the operating surface are backlit, which makes it easier for the vehicle occupant to locate the respective switching symbol to be switched. As soon as the relevant operating object, for example a finger of the vehicle occupant, approaches a particular switching symbol, which can be detected by the touch sensors, the associated function can already be activated so that the vehicle occupant does not even have to touch the switching symbol in question. Alternatively, it may be provided that the vehicle occupant has to touch the switching symbol in question in order to perform the function. As an alternative, it may be provided that touching the switching symbol will activate a further function assigned to the switching symbol. Analogously, a further function that is linked to the particular switching symbol may be activated by pressing the switching symbol, that is, exerting a mechanical pressure on the switching symbol in question.

In one embodiment, the motor vehicle operating device may include a maximum of n pressure sensors with n+2 touch sensors, where n is an integer>1. This allows an extremely high functionality of the motor vehicle operating device to be provided using n pressure sensors and n+2 touch sensors. Since each switching symbol is assigned one touch sensor, there are n+2 switching symbols with each of which one mechanical actuation can be detected, with fewer pressure sensors being provided than switching symbols. For example, six switching symbols are provided on the operating surface, and six touch sensors and four pressure sensors are provided.

According to one embodiment, the motor vehicle operating device comprises a circuit board, the touch sensors being arranged on a first circuit board surface of the circuit board associated with the operating surface. The touch sensors may be formed by means of electrodes which are arranged in the appropriate areas of the circuit board that are associated with the switching symbols.

For example, the operating surface is configured to be at least partly electrically conductive, so that together with the electrodes on the circuit board it forms the touch sensors. The operating surface may be provided on a cover plate which is a two-component injection molded part.

Furthermore, the pressure sensors may be arranged on a second circuit board surface opposite to the first circuit board surface. The first circuit board surface may be referred to as the front side, whereas the second circuit board surface may be referred to as the rear side. The second circuit board surface, i.e, the rear side, may be associated with a basic module of the motor vehicle operating device on which the pressure sensors are supported in order to convert an appropriately applied pressure into an electrical signal. This causes the distance between the capacitor plates of the capacitive pressure sensors to change if a pressure is applied, since the capacitor plates associated with the basic module cannot be displaced any further, so that their distance from the operating surface decreases. In an analogous way, in the case of piezoelectric pressure sensors, a pressure is generated that is converted into an electrical signal accordingly.

### BRIEF DESCRIPTION OF THE DRAWINGS

Further advantages and characteristics of the invention will be apparent from the description below and from the drawings to which reference is made and in which:

FIG. 1 shows an exploded view of a motor vehicle operating device according to the invention;

FIG. 2 shows the front side of a circuit board of the motor vehicle operating device according to the invention as shown in FIG. 1; and

FIG. 3 shows the rear side of the circuit board of the motor vehicle operating device according to the invention as shown in FIG. 1.

### DESCRIPTION

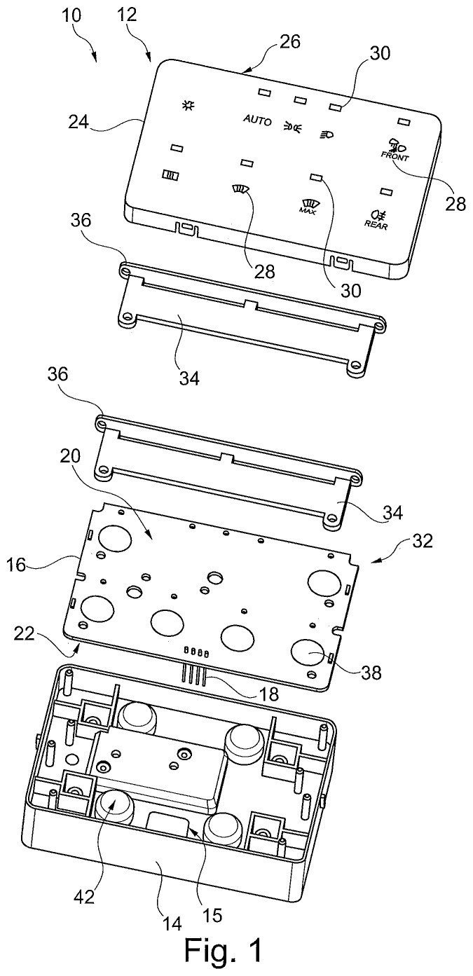

FIG. 1 shows a motor vehicle operating device 10 which, in the embodiment shown, is in the form of a light island 12.

The motor vehicle operating device 10 comprises a basic module 14 which comprises a plug chamber 15 into which a plug, not illustrated here, can be inserted for electrically connecting the motor vehicle operating device 10. Furthermore accommodated in the basic module 14 is a circuit board 16 that includes contact pins 18 which, in the assembled state, extend into the plug chamber 15 to be contacted by the plug.

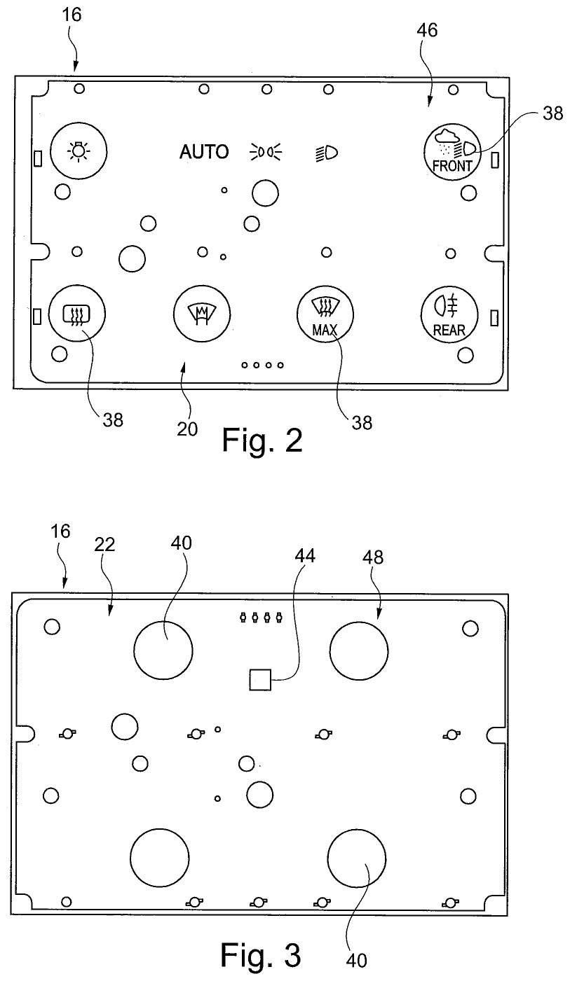

The circuit board 16 has a first circuit board surface 20 illustrated in FIG. 1, which may also be referred to as the front side (FIG. 2). Also, the circuit board 16 has a second circuit board surface 22 that is opposite to the first circuit board surface 20 and may also be referred to as the rear side (FIG. 3). The circuit board 16 is supported on the basic module 14 by means of the second circuit board surface 22, as will be discussed below.

The motor vehicle operating device further comprises a cover plate 24 forming an operating surface 26 on which a plurality of switching symbols 28 are depicted which have functions of the motor vehicle associated therewith which can be appropriately activated or deactivated by means of the switching symbols 28, as will be discussed below.

Furthermore provided in the cover plate 24, in particular the operating surface 26, are light exit surfaces 30, which may be used to visually display an activated function represented by the switching symbols 28.

The switching symbols 28 are made partially transparent so that they can be backlit by a search lighting 32. The search lighting 32 further includes optical fibers 34, which are also illustrated in FIG. 1. The optical fibers 34 are each delimited laterally by light partitions 36. This ensures that the functional light sources, which are assigned to the light exit surfaces 30 and are not shown in more detail on the circuit board 16, are not illuminated by the light emitted by the optical fibers 34.

As is apparent from FIGS. 2 and 3, in which the circuit board 16 is illustrated from the front and from the rear, the switching symbols 28 are assigned both touch sensors 38 and pressure sensors 40.

The touch sensors 38 are arranged on the first circuit board surface 20, which in the assembled state of the motor vehicle operating device 10 is associated with the operating surface 26. For example, the touch sensors 38 are configured as capacitive sensors, in particular self-capacitive sensors, so that they already detect an approach to a corresponding switching symbol 28. Accordingly, electrode areas are involved which are provided on the first circuit board surface 20. Alternatively, the touch sensors 38 may be configured as capacitive sensors which together with the operating surface 26 form a capacitor, the electric field of which is changed if the operating surface 26, which is configured to be partly electrically conductive, is touched.

The pressure sensors 40, by contrast, are arranged on the second circuit board surface 22, by means of which the circuit board 16 is supported on the basic module 14. As can be seen from FIG. 1, the basic module 14 includes suitably formed support surfaces 42 on which the pressure sensors 40 appropriately rest when the motor vehicle operating device 10 is in the assembled state.

The pressure sensors 40 may be configured as capacitive sensors, for example by two oppositely located capacitor plates, so that they convert a change in distance into a corresponding electrical signal. As an alternative, the pressure sensors 40 are configured as piezoelectric sensors so that they convert a pressure applied into an electrical signal. Generally, the plurality of pressure sensors 40 may also be of mixed configurations, that is, partly as capacitive sensors and the other part as piezoelectric sensors.

In general, the circuit board 16 may comprise an evaluation unit 44 (see FIG. 3) which is coupled to the touch sensors 38 and the pressure sensors 40 in order to detect different operating or actuating scenarios.

The touch sensors 38 together form a touch sensor system 46 by means of which an approach to the operating surface 26 or a particular switching symbol 28 and/or a touch of the respective switching symbol 28 can be detected and located. This is due to the fact that each switching symbol 28 is assigned a touch sensor 38.

In general, the touch sensor system 46 may be formed by a capacitive film having a matrix structure, so that the individual touch sensors 38 are formed. For evaluation, the evaluation unit 44 may have a corresponding allocation table stored therein, which is used to allocate the signal values of the touch sensor system 46 to the respective switching symbols 28 or the touch sensors 38 assigned to the switching symbols 28.

Furthermore, the pressure sensors 40 together form an actuation sensor system 48 by means of which a mechanical actuation of the motor vehicle operating device 10, in particular the operating surface 26, can be detected. In addition, the plurality of pressure sensors 40 can be indicative of the place where pressure is exerted, in particular by means of a triangulation process. This allows a spatially resolved actuation detection to be effected.

The pressure sensors 40 are more particularly substantially homogeneously distributed over the circuit board 16 to allow the best possible detection of the actuation of the operating surface 26 in this way.

A first operating scenario may consist in that the plurality of touch sensors 38 detect an approach to the operating surface 24, for example to activate the search lighting 32, so that the switching symbols 28 are each backlit. Accordingly, the search lighting light sources, for example LEDs, are activated.

If a finger of a vehicle occupant approaches a particular switching symbol 28, this is also detected by the associated touch sensor 38, so that a first function assigned to the respective switching symbol 28 can be activated. For example, the rear fog lamp is activated when the vehicle occupant's finger approaches the appropriate switching symbol 28.

Alternatively, provision may be made for the vehicle occupant to be required to touch the operating surface 24, in particular the switching symbol 28 concerned, with his or her finger in order to activate the first function.

Furthermore, it may be provided that a switching symbol 28 has a plurality of functions assigned to it, which are activated as a function of the operation, i.e., for example, by approaching, touching or mechanically pressing. For example, for the front headlights it is provided that an approach to the corresponding switching symbol 28 results in a parking light being switched on, whereas touching the switching symbol 28 in question activates the automatic light setting (activating the dimmed headlights if a light sensor detects that this is necessary). Mechanically pressing the respective switching symbol 28, on the other hand, is assessed as switching on the light even though the automatic light setting would not yet provide for this since it is bright enough, for example.

As an alternative, mechanically pressing via the actuation sensor system 48 may merely serve to confirm the touch of the respective switching symbol 28 which was previously detected by the touch sensor system 46. This allows an unintended touching of a switching symbol 28 and the otherwise attendant unintentional activation of the assigned switching function to be prevented.

Due to the triangulation procedure taking into account the limits of the operating surface 26, it is possible to infer the appropriately actuated switching symbol 28 despite the reduced number of pressure sensors 40 in comparison to the number of switching symbols 28.

In general, each of the plurality of switching symbols 28 has a proximity or touch sensor system 46 and also an actuation sensor system 48 assigned to it, while not each switching symbol 28 has a respective pressure sensor 40 assigned to it.

The reason for this is that initially the approach or touch is detected by the corresponding touch sensor system 46, whereas afterwards an actuation of the operating surface 26 is generally detected by the pressure sensors 40, i.e. the actuation sensor system 48.

Since the plurality of pressure sensors 40 are arranged distributed over the second circuit board surface 22, the signals respectively output by the pressure sensors 40 can be evaluated among each other in order to determine by means of a triangulation method at which position a switching symbol 28 has been pressed. This information can be made use of as a plausibility check for the touch sensors 38, by means of which initially the corresponding approach to the switching symbol 28 has already been detected.

In addition to the pure evaluation of the mechanical actuation, the evaluation unit 44 can also evaluate the time course of the forces acquired, to use it to activate or deactivate a further function.

Also, the evaluation unit 44 can continuously monitor the actuation sensor system 48 so that a force signal is generated, a different function being performed in case of a higher force. For example, the light intensity is increased faster if the pertinent switching symbol 28 is pressed with a higher force, if it is associated with an interior lighting.

Moreover, an actuation threshold may be provided which, in particular, is programmable. Accordingly, the force or the pressure may be adjusted as from which the actuation sensor system 48 is activated or recognizes a pressing action as an actuation.

Furthermore, the evaluation unit 44 in combination with the touch sensor system 46 allows the size of the area of the operating surface 26 to be recognized that is actuated simultaneously in order to use this to infer the pressure that has been applied. This in turn can be correlated with the data captured by the actuation sensor system 48.

As an alternative to the light island 12 shown, which includes switching symbols 28 in two rows, a light strip may be provided as a motor vehicle operating device 10, which comprises the switching symbols 28 in one row.

In this way it is possible to attain a high functionality of the motor vehicle operating device 10 with few pressure sensors 40, in particular to assign a plurality of, for example n+2, switching symbols 28 to an actuation sensor system, although only n pressure sensors 40 are provided.

1. A motor vehicle operating device (10) for an interior of a motor vehicle, comprising an operating surface (26) which has a plurality of switching symbols (28) displayed thereon, each of which having a touch sensor (38) associated therewith, the touch sensors (38) each being configured to detect an approach to and/or a touch of the operating surface (26), the motor vehicle operating device (10) further comprising a plurality of pressure sensors (40) which are associated with the switching symbols (28), the number of pressure sensors (40) being smaller than the number of touch sensors (38).

2. The motor vehicle operating device (10) according to claim 1, wherein the touch sensors (38) and/or the pressure sensors (40) are designed to be capacitive and/or piezoelectric.

3. The motor vehicle operating device (10) according to claim 1, wherein the motor vehicle operating device (10) comprises an evaluation unit (44) which is coupled to the touch sensors (38) and the pressure sensors (40) in order to evaluate the data acquired.

4. The motor vehicle operating device (10) according to claim 1, wherein the touch sensors (38) form a touch sensor system (46) which is configured to detect and locate an approach to and/or a touch of the operating surface (26).

5. The motor vehicle operating device (10) according to claim 1, wherein the pressure sensors (40) form an actuation sensor system (48) which is configured to detect a pressure on the operating surface (26).

6. The motor vehicle operating device (10) according to claim 4, wherein the touch sensor system (46) and the actuation sensor system (48) are configured in such a way that together they detect an actuation of one of the plurality of switching symbols (28).

7. The motor vehicle operating device (10) according to claim 1, wherein the motor vehicle operating device (10) is configured to detect an approach to the entire operating surface (26), an approach to one of the plurality of switching symbols (28), a touch of one of the plurality of switching symbols (28) and/or a pressing of one of the plurality of switching symbols (28), in particular wherein different functions are associated with the detected states.

8. The motor vehicle operating device (10) according to claim 1, wherein the motor vehicle operating device (10) includes a maximum of n pressure sensors (40) with n+2 touch sensors (38), n being an integer greater than 1.

9. The motor vehicle operating device (10) according to claim 1, wherein the motor vehicle operating device comprises a circuit board (16), the touch sensors (38) being arranged on a first circuit board surface (20) of the circuit board (16) associated with the operating surface (26).

10. The motor vehicle operating device (10) according to claim 9, wherein the pressure sensors (40) are arranged on a second circuit board surface (22) opposite to the first circuit board surface (20).
